(19) United States
(12) Patent Application Publication
(10) Pub. No.: US 2026/0372172 A1
(43) Pub. Date: Nov. 19, 2026

(54) SEMICONDUCTOR PACKAGE BASED ON WIRE FINGER AND METHOD OF MANUFACTURING THE SAME

(71) Applicant: SAMSUNG ELECTRONICS CO., LTD., SUWON-SI (KR)

(72) Inventor: Geming WU, Suzhou (CN)

(73) Assignee: SAMSUNG ELECTRONICS CO., LTD., SUWON-SI (KR)

(21) Appl. No.: 19/252,582

(22) Filed: Jun. 27, 2025

(30) Foreign Application Priority Data
May 16, 2025 (CN) 202510638065.7

(51) Int. Cl. H10W 74/10; H10W 70/60; H10W 70/685; H10W 72/59; H10W 72/90; H10W 74/40; H10W 90/00

(52) U.S. Cl. CPC H10W 74/117; H10W 70/611; H10W 70/685; H10W 74/40; H10W 90/00; H10W 72/59; H10W 72/967; H10W 90/754

(57) ABSTRACT

A semiconductor package includes a substrate; first chips stacked on the substrate and electrically connected to the substrate through a first bonding wire; a second chip disposed on the substrate and spaced apart from the first chips in a first direction parallel to an upper surface of the substrate, wherein the second chip includes a dummy pad disposed on an upper surface of the second chip and a wire finger disposed on the dummy pad and electrically connected to the substrate through a second bonding wire; a first plastic-encapsulated body covering the first chips and the second chip on the substrate and exposing an upper surface of the wire finger; a third chip disposed on an upper surface of the first plastic-encapsulated body and electrically connected to the wire finger through a third bonding wire; and a second plastic-encapsulated body covering the third chip on the first plastic-encapsulated body.

### CROSS-REFERENCE TO RELATED APPLICATION

This application claims priority to the Chinese Patent Application No. 202510638065.7 filed on May 16, 2025, in the China National Intellectual Property Administration, the disclosure of which is incorporated by reference herein in its entirety.

### TECHNICAL FIELD

Embodiments of the present disclosure relate to the field of semiconductor package, and particularly relate to a semiconductor package based on a wire finger and a method of manufacturing the same.

### BACKGROUND ART

In the related art, a multi-chip package may typically encapsulate a plurality of chips with different functions in one package. Current multi-chip packages are composed of semiconductor chips, metal wires, wafer bonding films, plastic encapsulants, substrates, etc. A wire bonding pad is disposed on a semiconductor chip. In the related art, interconnection between a semiconductor chip and a substrate is implemented based on a wire bonding technique, and the semiconductor chip and a circuit are protected from an external environment by plastic encapsulation using a plastic encapsulant. External terminals (e.g., solder balls) are disposed on a surface of the substrate opposite to a surface on which the semiconductor chip is mounted, and the multi-chip package is finally soldered to a circuit board of an end product through the external terminals by a surface mount (SMT) process, thereby implementing electrical connection of the semiconductor chip to external elements.

Generally, since the sizes of semiconductor chips having various different functions included in the multi-chip package are different from each other, reliability problem of the multi-chip package may be caused.

The above information disclosed in the part of Background Art is merely used for enhancing understanding of the technical background of the present disclosure. Thus, the above information may contain information that does not form prior art already known to those skilled in the art in this country.

### SUMMARY

In order to solve the above problem, the embodiments of the present disclosure disclose a semiconductor package based on a wire finger and a method of manufacturing the semiconductor package, which may reduce voids in a plastic-encapsulated body and/or suppress warping.

According to an aspect of the present disclosure, there is provided a semiconductor package, including: a substrate; a plurality of first chips stacked on the substrate, each of the plurality of first chips being electrically connected to the substrate through a first bonding wire; a second chip disposed on the substrate and spaced apart from the plurality of first chips in a first direction parallel to an upper surface of the substrate, wherein the second chip includes a dummy pad disposed on an upper surface of the second chip and a wire finger disposed on the dummy pad, and the wire finger is electrically connected to the substrate through a second bonding wire; a first plastic-encapsulated body covering the plurality of first chips and the second chip on the substrate and exposing an upper surface of the wire finger; a third chip disposed on an upper surface of the first plastic-encapsulated body and electrically connected to the wire finger through a third bonding wire; and a second plastic-encapsulated body covering the third chip on the first plastic-encapsulated body.

Preferably, a first distance between the upper surface of the wire finger and the upper surface of the substrate in the second direction may be equal to or greater than a thickness between the upper surface of the first plastic-encapsulated body and the upper surface of the substrate in the second direction.

Preferably, the wire finger may include at least one conductive connecting part stacked in the second direction, an upper surface of an uppermost conductive connecting part of the at least one conductive connecting part being exposed from the first plastic-encapsulated body.

Preferably, each of the at least one conductive connecting part may be a metal ball.

Preferably, the second bonding wire may be connected to a lowermost conductive connecting part of the at least one conductive connecting part.

Preferably, the second chip may be a circuit chip having an electrical function, and the second chip may be electrically connected to the substrate through a fourth bonding wire.

Preferably, the semiconductor chip may further include: a functional pad disposed on the upper surface of the second chip and spaced apart from the dummy pad in the first direction, wherein the fourth bonding wire is connected to the functional pad and the substrate.

Preferably, the second chip may be a dummy chip not having an electrical function.

Preferably, the dummy pad and the wire finger may be arranged in at least one column on the upper surface of the second chip.

Preferably, the thickness of the first plastic-encapsulated body may be greater than a thickness of the second plastic-encapsulated body between an upper surface of the second plastic-encapsulated body and the upper surface of the first plastic-encapsulated body in the second direction.

Preferably, the first plastic-encapsulated body and the second plastic-encapsulated body may be formed of different materials.

Preferably, the third chip is in plural and electrically connected to each other through the third bonding wire.

According to another aspect of the present disclosure, there is provided a method of manufacturing a semiconductor package, including: providing a substrate; stacking a plurality of first chips on the substrate, and electrically connecting each of the plurality of first chips to the substrate through a first bonding wire; disposing a second chip on the substrate, the second chip being spaced apart from the plurality of first chips in a first direction parallel to an upper surface of the substrate, wherein the second chip includes a dummy pad disposed on an upper surface of the second chip; disposing a wire finger on the dummy pad and electrically connecting the wire finger to the substrate through a second bonding wire; performing a first plastic-encapsulating process to form a first plastic-encapsulated body, the first plastic-encapsulated body covering the plurality of first chips and the second chip on the substrate and exposing an upper surface of the wire finger; disposing a third chip on an upper surface of the first plastic-encapsulated body and electrically connecting the third chip to the wire finger through a third bonding wire; and performing a second plastic-encapsulating process to form a second plastic-encapsulated body, the second plastic-encapsulated body covering the third chip on the first plastic-encapsulated body.

Preferably, a first distance between the upper surface of the wire finger and the upper surface of the substrate in the second direction may be equal to or greater than a thickness of the first plastic-encapsulated body between the upper surface of the first plastic-encapsulated body and the upper surface of the substrate in the second direction.

Preferably, the disposing of the wire finger may include: at least one conductive connecting part may be stacked in a second direction perpendicular to the upper surface of the substrate, and the performing of the first plastic-encapsulating process may include; an upper surface of an uppermost conductive connecting part of the at least one conductive connecting part may be exposed from the first plastic-encapsulated body.

Preferably, each of the at least one conductive connecting part may be a metal ball.

Preferably, the second bonding wire may be connected to a lowermost conductive connecting part of the at least one conductive connecting part.

Preferably, the second chip may be a circuit chip having an electrical function, and the disposing of the second chip may further include: the second chip may be electrically connected to the substrate through a fourth bonding wire.

Preferably, the semiconductor chip may further include: a functional pad disposed on the upper surface of the second chip and spaced apart from the dummy pad in the first direction, wherein the fourth bonding wire is connected to the functional pad and the substrate.

Preferably, the second chip may be a dummy chip not having an electrical function.

Preferably, the dummy pad and the wire finger may be arranged in at least one column on the upper surface of the second chip.

Preferably, the thickness of the first plastic-encapsulated body may be greater than a thickness of the second plastic-encapsulated body between an upper surface of the second plastic-encapsulated body and the upper surface of the first plastic-encapsulated body in the second direction.

Preferably, the first plastic-encapsulated body and the second plastic-encapsulated body may be formed of different materials.

Preferably, the third chip may be disposed to be plural and may be electrically connected to each other through the third bonding wire.

### BRIEF DESCRIPTION OF THE DRAWINGS

The above and other features and advantages of the present disclosure will become apparent from the following detailed description for embodiments of the present disclosure, taken in conjunction with the drawings. In the drawings, the same reference signs always indicate the same elements.

FIG. 1 is a sectional view of a semiconductor package according to an embodiment of the present disclosure.

FIG. 2 is a sectional view of a semiconductor package according to a comparative example.

FIG. 3 is a flowchart of a method of manufacturing a semiconductor package according to an embodiment of the present disclosure.

FIG. 4, FIG. 5, FIG. 6 and FIG. 7 are sectional views of an intermediate stage of the method of manufacturing the semiconductor package according to embodiments of the present disclosure.

### DETAILED DESCRIPTION OF EXEMPLARY EMBODIMENTS

Various embodiments of the present disclosure will be sufficiently described below by referring to drawings of some illustrated embodiments. However, the present disclosure may be implemented in many different forms, and should not be interpreted to be limited to the embodiments elaborated hereto.

For easy description, spatial relevancy terms (such as “below”, “under”, “above”, “on”, etc.) may be used herein to describe a relationship between one component and the other component as illustrated in the drawings. It should be understood that, the spatial relevancy terms also intend to include different orientations of a device in a usage or an operation, other than the orientations as painted in the drawings. For example, if the device in the drawings is flipped, the component described to be “below” or “under” the other component previously shall be oriented as “above” the other component subsequently. Therefore, the term “under” may include two orientations of “above” and “under”.

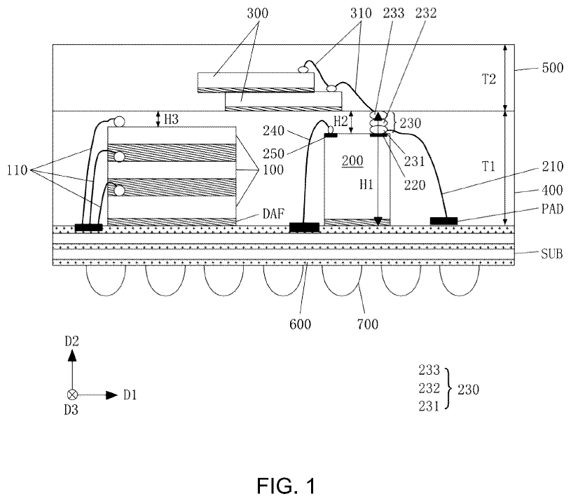

FIG. 1 is a sectional view of a semiconductor package according to an embodiment of the present disclosure.

Referring to FIG. 1, a semiconductor package 1000 includes: a substrate SUB; a plurality of first chips 100 stacked on the substrate SUB, each of the plurality of first chips 100 being electrically connected to the substrate SUB through a first bonding wire 110; a second chip 200 disposed on the substrate SUB and spaced apart from the plurality of first chips 100 in a first direction D1 parallel to an upper surface of the substrate SUB, wherein the second chip 200 includes a dummy pad 220 disposed on an upper surface of the second chip 200 and a wire finger 230 disposed on the dummy pad 220, and the wire finger 230 is electrically connected to the substrate SUB through a second bonding wire 210; a first plastic-encapsulated body 400 covering the plurality of first chips 100 and the second chip 200 on the substrate SUB and exposing an upper surface of the wire finger 230; a third chip 300 disposed on an upper surface of the first plastic-encapsulated body 400 and electrically connected to the wire finger 230 through a third bonding wire 310; and a second plastic-encapsulated body 500 covering the third chip 300 on the first plastic-encapsulated body 400.

In one embodiment, the substrate SUB may be a printed circuit board. For example, the substrate SUB may include a multilayer wiring 600, a plurality of vias interconnecting the multilayer wiring 600, a pad PAD disposed on the upper surface of the substrate SUB, and an external connecting terminal 700 disposed on a lower surface of the substrate SUB. In this case, the semiconductor package 1000 may be a system-level package structure including a plurality of package chips, and may be electrically connected to an external device through the external connecting terminal 700.

A plurality of first chips 100 may be a circuit chip having an electrical function, for example, a memory chip or a logic chip. In one embodiment, an active surface of each of the plurality of first chips 100 may be disposed facing upward. The first bonding wire 110 may be connected to a connecting pad disposed on the active surface of the each first chip 100 and a pad PAD disposed on the substrate SUB, respectively, so that the first chip 100 may be electrically interconnected with the substrate SUB.

In one embodiment, the plurality of first chips 100 may be sequentially stacked on the substrate SUB in a second direction D2 perpendicular to the upper surface of the substrate SUB to form a first chip stack. A die attach film DAF may be disposed between the first chips 100 adjacent to each other. In one embodiment, a material of the first bonding wire 110 may be gold (Au), but the present disclosure is not limited thereto.

In one embodiment, the third chip 300 may be disposed to be plural and may be electrically connected to each other through the third bonding wire 310. For example, the plurality of first chips 100 may be sequentially stacked on the first plastic-encapsulated body 400 in the second direction D2 perpendicular to the upper surface of the substrate SUB to form a second chip stack. The die attach film DAF may also be disposed between the third chips 300 adjacent to each other. The third chip 300 may also be a circuit chip having an electrical function. However, the third chip 300 may have an electrical function different from that of the first chip 100.

In one embodiment, the first plastic-encapsulated body 400 and the second plastic-encapsulated body 500 may be formed of different materials. For example, the first plastic-encapsulated body 400 may include an epoxy resin (EMC). The second plastic-encapsulated body 500 may include a material that is more rigid than EMC. In this case, since the second plastic-encapsulated body 500 is disposed above the first plastic-encapsulated body 400 and has greater rigidity, warping of the semiconductor package 1000 may be prevented. In addition, the first plastic-encapsulated body 400 may be formed of a material having greater fluidity than that of the second plastic-encapsulated body 500, so that during the first plastic-encapsulating process, voids or pores caused by poor filling of plastic encapsulants may be reduced, and further the product yield may be improved.

In one embodiment, a thickness T1 of the first plastic-encapsulated body 400 in which the thickness T1 is a length between the upper surface of the first plastic-encapsulated body 400 and the upper surface of the substrate SUB in the second direction D2 may be greater than a thickness T2 of the second plastic-encapsulated body 500 in the second direction. In this case, the number of the third chips 300 may be less than the number of the first chips 100, and a thickness of the second chip stack may be less than a thickness of the first chip stack.

In one embodiment, a first distance H1 between the upper surface of the wire finger 230 and the upper surface of the substrate SUB in the second direction D2 may be equal to or greater than the thickness T1 of the first plastic-encapsulated body 400 in the second direction D2. In this case, the third chip 300 may be electrically connected to the exposed upper surface of the wire finger 230 through the third bonding wire 310.

In one embodiment, the wire finger 230 may include at least one conductive connecting part 231, 232 and 233 stacked in the second direction D2 perpendicular to the upper surface of the substrate SUB. An upper surface of an uppermost conductive connecting part 233 of the at least one conductive connecting part 231, 232 and 233 may be exposed from the first plastic-encapsulated body 400. A lowermost third chip of the third chips 300 may be electrically connected to an exposed upper surface of the uppermost conductive connecting part 233 through the third bonding wire 310.

The conductive connecting parts 231, 232 and 233 may be stacked on each other in the second direction D2 to form the wire finger 230. A second distance H2 between the exposed upper surface of the wire finger 230 and the upper surface of the second chip 200 in the second direction D2 may be equal to a sum of heights of the conductive connecting parts 231, 232 and 233 in the second direction D2.

In one embodiment, each of the at least one conductive connecting part 231, 232 and 233 may be a metal ball. For example, each of the conductive connecting parts 231, 232 and 233 may be a gold wire ball formed directly when the second bonding wire 210 is formed. For example, a material of the second bonding wire 210 may be Au and a material of the gold wire ball may be the same as that of the second bonding wire 210. The second distance H2 may be equal to a sum of diameters of each metal ball (e.g., a gold wire ball). In this case, the second bonding wire 210 may be connected to the lowermost conductive connecting part 231 of the conductive connecting parts 231, 232 and 233, so that the third chip 300 may be electrically connected to the pad PAD on the substrate SUB through the third bonding wire 310, the wire finger 230, the dummy pad 220 and the second bonding wire 210.

In addition, a third distance H3 between the upper surface of the first plastic-encapsulated body 400 and an upper surface of an uppermost first chip of the plurality of first chips 100 in the second direction D2 may be less than the second distance H2. In this case, the thickness of the second chip 200 in the second direction D2 may be less than the thickness of the first chip stack in the second direction D2.

In one embodiment, the second chip 200 may be a circuit chip having an electrical function, and the second chip 200 may be electrically connected to the substrate SUB through a fourth bonding wire 240.

Particularly, the second chip 200 may further include: a functional pad 250 disposed on the upper surface of the second chip 200 and spaced apart from the dummy pad 220 in the first direction D1, wherein the fourth bonding wire 240 is connected to the functional pad 250. In this case, a signal from an external device may be transmitted to the second chip 200 through the external connecting terminal 700, the multilayer wiring 600, the pad PAD, the fourth bonding wire 240 and the functional pad 250, or the second chip 200 may transmit the signal to the external device through the functional pad 250, the fourth bonding wire 240, the pad PAD, the multilayer wiring 600 and the external connecting terminal 700.

In another embodiment, unlike what is shown in FIG. 1, the second chip 200 may be a dummy chip not having an electrical function. In this case, the fourth bonding wire 240 and the functional pad 250 in FIG. 1 may be omitted. The dummy pad 220 and the wire finger 230 may be arranged in at least one column in a third direction D3 perpendicular to the first direction D1 and the second direction D2 on the upper surface of the second chip 200. Therefore, more connecting points may be provided to the upper third chip 300 to increase an integration level of the semiconductor package 1000.

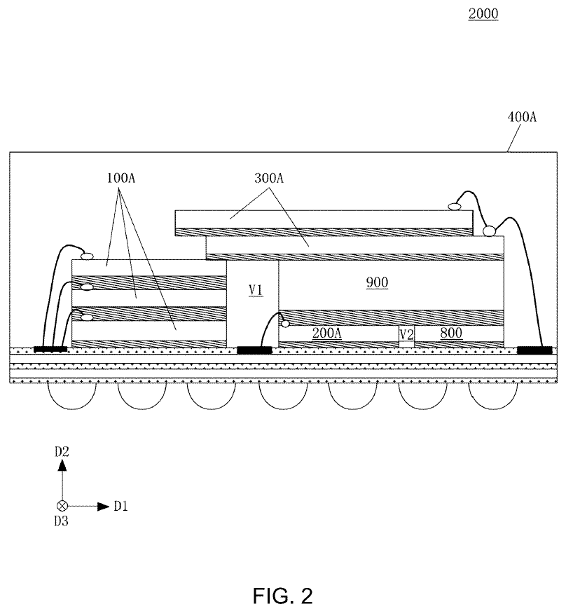

FIG. 2 is a sectional view of a semiconductor package according to a comparative example.

Referring to FIG. 2, a semiconductor package 2000 includes a first chip 100A, a second chip 200A and a third chip 300A corresponding to the first chip 100, the second chip 200 and the third chip 300 in the semiconductor package 1000 shown in FIG. 1. In addition, the semiconductor package 2000 further includes a first dummy chip 800 and a second dummy chip 900. The first dummy chip 800 has a thickness the same as that of the second chip 200A in the second direction D2 and is disposed to be spaced apart from the second chip 200A in the first direction D1. The second dummy chip 900 is stacked on the second chip 200A and the first dummy chip 800 so that an upper surface of the second dummy chip 900 is disposed at the same height as an upper surface of an uppermost first chip of the plurality of first chips 100A stacked in the second direction D2. The third chip 300A may be disposed to be plural and stacked on the uppermost first chip and the second dummy chip 900.

Generally, the sizes of chips having various different functions are different. In order to package all these chips of different sizes in one package structure, it is necessary to introduce some dummy chips or buffer chips that have no actual functions, such as the first dummy chip 800 and the second dummy chip 900 in the semiconductor package 2000, to compensate for the size difference between the different chips. This will lead to many tunnel structures within the package structure.

In the above structure of the semiconductor package 2000, a plurality of tunnel structures will be formed. For example, a tunnel structure V1 may be disposed between a sidewall of the stacked plurality of first chips 100A and a sidewall of the stacked second chip 200A and second dummy chip 900. A tunnel structure V2 may be disposed between a sidewall of the first dummy chip 800 and a sidewall of the second chip 200A that are spaced apart from each other. During the plastic-encapsulating process, it is difficult to fill plastic encapsulants completely into these tunnel structures, resulting in voids in the tunnel structures, thereby causing reliability problem of a product.

A semiconductor package structure according to embodiments of the present disclosure may include a first plastic-encapsulated body 400 and a second plastic-encapsulated body 500 disposed on the first plastic-encapsulated body 400. The second chip 200 may be packaged in the first plastic-encapsulated body 400, and may have the dummy pad 220 and the wire finger 230 disposed on the upper surface thereof. The third chip 300 disposed above the second chip 200 and packaged in the second plastic-encapsulated body 500 may be electrically connected to the substrate SUB through the wire finger 230. As a result, the aforementioned tunnel structures may be eliminated, and the formation of voids in the first plastic-encapsulated body 400 and the second plastic-encapsulated body 500 may be avoided. Therefore, the reliability of the semiconductor package may be improved.

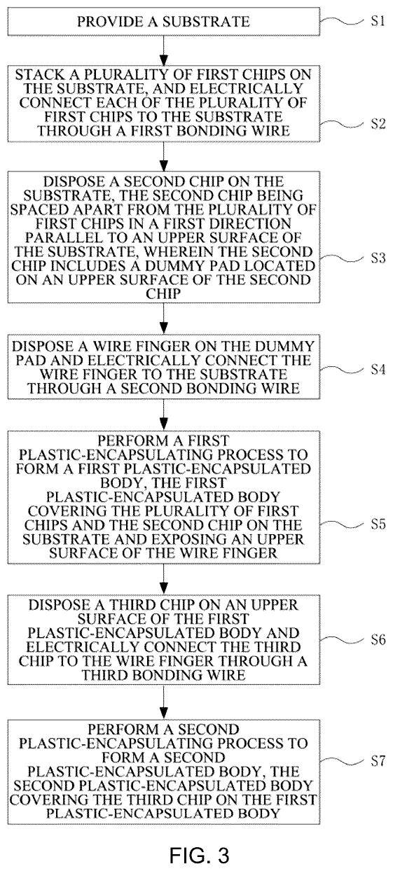

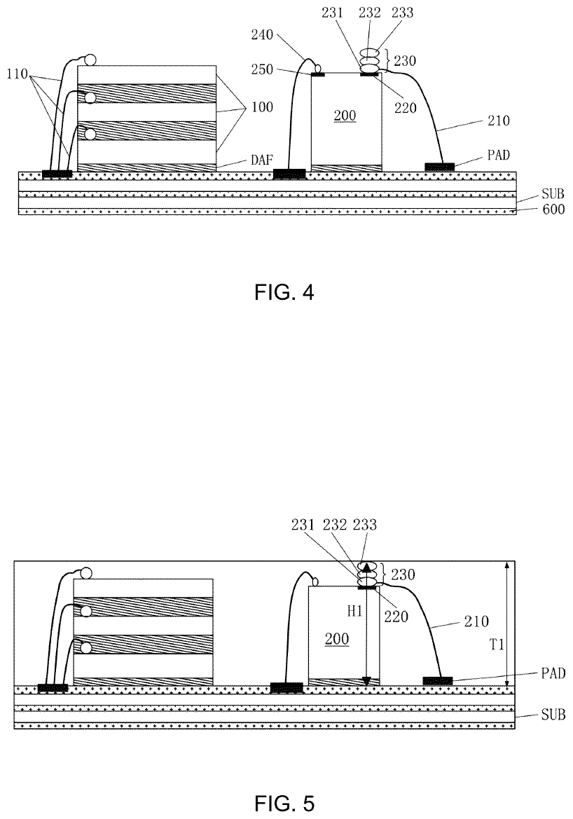

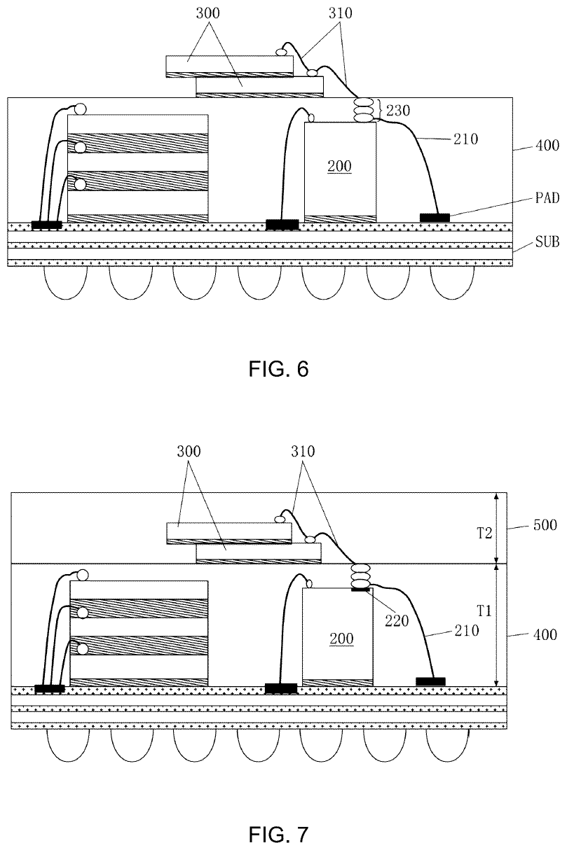

Hereinafter, a method of manufacturing a semiconductor package according to embodiments of the present disclosure will be described. FIG. 3 is a flowchart of a method of manufacturing a semiconductor package according to an embodiment of the present disclosure. FIGS. 4-7 are sectional views of an intermediate stage of the method of manufacturing the semiconductor package according to embodiments of the present disclosure.

The semiconductor package described in FIGS. 3-7 may be the semiconductor package 1000 shown in FIG. 1. Referring to FIGS. 3 and 4, the method of manufacturing the semiconductor package includes: in step S1, a substrate SUB is provided. For example, the substrate SUB may be a printed circuit board. The substrate SUB may include a multilayer wiring 600 and a plurality of vias.

In step S2, a plurality of first chips 100 are stacked on the substrate SUB, and each of the plurality of first chips 100 is electrically connected to the substrate SUB through a first bonding wire 100. Each of the plurality of first chips 100 may be a chip having an electrical function, for example, a memory chip or a logic chip.

In step S3, a second chip 200 is disposed on the substrate SUB. The second chip 200 is spaced apart from the plurality of first chips 100 in a first direction D1 parallel to an upper surface of the substrate SUB. The second chip 200 includes a dummy pad 220 disposed on an upper surface thereof. Here, the dummy pad 220 may be added onto the second chip 200 in advance, and may not be electrically connected to other pads of the second chip 200. That is, the dummy pad 220 may only function as a relay element that electrically connects the third chip 300 to the substrate SUB, and does not participate in or constitute a circuit pattern of the second chip 200.

In step S4, a wire finger 230 is disposed on the dummy pad 220 and electrically connected to the substrate SUB through a second bonding wire 210.

In one embodiment, the step S4 of disposing the wire finger may include: stacking at least one conductive connecting part 231, 232 and 233 in a second direction D2. Here, each of the conductive connecting parts 231, 232 and 233 may be a metal ball, for example, a gold wire ball. In this case, the second bonding wire 210 may be connected to a lowermost conductive connecting part 231 of the conductive connecting parts 231, 232 and 233.

In one embodiment, the second chip 200 may be a circuit chip having an electrical function, and the step S3 of disposing the second chip may further include: the second chip 200 may be electrically connected to the substrate SUB through a fourth bonding wire 240.

Particularly, the second chip 200 may further include: a functional pad 250 disposed on the upper surface of the second chip 200 and spaced apart from the dummy pad 230 in the first direction D1, wherein the fourth bonding wire 240 is connected to the functional pad 250.

In another embodiment, the second chip 200 may be a dummy chip or a buffer chip not having an electrical function. In this case, the function pad and the fourth bonding wire may be omitted, and the dummy pad 220 and the wire finger 230 may be arranged in at least one column on the upper surface of the second chip 200.

Referring to FIGS. 3 and 5, in step S5, a first plastic-encapsulating process P1 is performed to form a first plastic-encapsulated body 400. The first plastic-encapsulated body 400 covers the plurality of first chips 100 and the second chip 200 on the substrate SUB and exposes an upper surface of the wire finger 230.

In one embodiment, the step S5 of performing the first plastic-encapsulating process may include: exposing an upper surface of an uppermost conductive connecting part 233 of the at least one conductive connecting part 231, 232 and 233 from the first plastic-encapsulated body 400. In this case, a first distance H1 between the exposed upper surface of the wire finger 230 and the upper surface of the substrate SUB in the second direction D2 may be equal to or greater than a thickness T1 of the first plastic-encapsulated body 400 in the second direction D2.

For example, as shown in FIG. 5, when the first plastic-encapsulating process P1 is performed, the thickness T1 of the first plastic-encapsulated body 400 in the second direction D2 may be formed to be equal to or slightly less than a height H1 of the upper surface of the wire finger 230 from the upper surface of the substrate SUB in the second direction D2. In this case, during the first plastic-encapsulating process P1, an uppermost metal ball 233 in the wire finger 230 will be pushed into a release film at a bottom of a plastic encapsulant. Therefore, at the end of the first plastic-encapsulating process P1, an upper surface of the uppermost metal ball 233 may be directly exposed to the outside, and function as a wire finger in the subsequent wire bonding process.

Referring to FIGS. 3 and 6, in step S6, a third chip 300 may be disposed on an upper surface of the first plastic-encapsulated body 400 and electrically connected to the wire finger 230 through a third bonding wire 310. In one embodiment, the third chip 300 may be disposed to be plural and electrically connected to each other through the third bonding wire 310.

Referring to FIGS. 3 and 7, in step S7, a second plastic-encapsulating process P2 is performed to form a second plastic-encapsulated body 500. The second plastic-encapsulated body 500 covers the third chip 300 on the first plastic-encapsulated body 400. In one embodiment, a thickness T1 of the first plastic-encapsulated body 400 in the second direction D2 may be greater than a thickness T2 of the second plastic-encapsulated body 500 in the second direction D2. The first plastic-encapsulated body 400 and the second plastic-encapsulated body 500 may be formed of different materials.

As a summary and review, according to embodiments of the present disclosure, a first plastic-encapsulated body and a second plastic-encapsulated body stacked vertically may be formed through multiple times of plastic-encapsulating processes. A dummy pad and a wire finger disposed on a second chip may be encapsulated in the first plastic-encapsulated body, and a third chip disposed above the second chip may be encapsulated in the second plastic-encapsulated body. The third chip may be electrically interconnected through the dummy pad and the wire finger to replace a through molding via in a wire bonding manner. Therefore, voids in the plastic-encapsulated body may be avoided, the structure of a multi-chip package (MCP) may be simplified, and its reliability may be improved. In addition, the method of manufacturing the semiconductor package of the present disclosure may use conventional packaging processes and devices, and does not need to additionally use new processes or devices, thereby saving production costs.

Although the embodiments of the present disclosure have been illustrated and described here, it will be understood by those skilled in the art that various modifications and changes may be made therein without departing from the spirit and scope of the present disclosure as defined by the claims.

What is claimed is:

1. A semiconductor package comprising:
a substrate;
a plurality of first chips stacked on the substrate, each of the plurality of first chips being electrically connected to the substrate through a first bonding wire;
a second chip disposed on the substrate and spaced apart from the plurality of first chips in a first direction parallel to an upper surface of the substrate, wherein the second chip comprises a dummy pad disposed on an upper surface of the second chip and a wire finger disposed on the dummy pad, and the wire finger is electrically connected to the substrate through a second bonding wire;
a first plastic-encapsulated body covering the plurality of first chips and the second chip on the substrate and exposing an upper surface of the wire finger;
a third chip disposed on an upper surface of the first plastic-encapsulated body and electrically connected to the wire finger through a third bonding wire; and
a second plastic-encapsulated body covering the third chip on the first plastic-encapsulated body.

2. The semiconductor package of claim 1, wherein a first distance between the upper surface of the wire finger and the upper surface of the substrate in a second direction perpendicular to the upper surface of the substrate is equal to or greater than a thickness of the first plastic-encapsulated body between the upper surface of the first plastic-encapsulated body and the upper surface of the substrate in the second direction.

3. The semiconductor package of claim 2, wherein the wire finger comprises at least one conductive connecting part stacked in the second direction, and an upper surface of an uppermost conductive connecting part of the at least one conductive connecting part is exposed from the first plastic-encapsulated body.

4. The semiconductor package of claim 3, wherein each of the at least one conductive connecting part is a metal ball.

5. The semiconductor package of claim 3, wherein the second bonding wire is connected to a lowermost conductive connecting part of the at least one conductive connecting part, wherein the lowermost conductive connecting part is disposed on the dummy pad.

6. The semiconductor package of claim 1, wherein the second chip is a circuit chip having an electrical function, and the second chip is electrically connected to the substrate through a fourth bonding wire.

7. The semiconductor package of claim 6, wherein the second chip further comprises:
a functional pad disposed on the upper surface of the second chip and spaced apart from the dummy pad in the first direction,
wherein the fourth bonding wire is connected to the functional pad and the substrate.

8. The semiconductor package of claim 1, wherein the second chip is a dummy chip not having an electrical function.

9. The semiconductor package of claim 8, wherein the dummy pad and the wire finger are arranged in at least one column on the upper surface of the second chip.

10. The semiconductor package of claim 2, wherein the thickness of the first plastic-encapsulated body is greater than a thickness of the second plastic-encapsulated body between an upper surface of the second plastic-encapsulated body and the upper surface of the first plastic-encapsulated body in the second direction.

11. The semiconductor package of claim 1, wherein the first plastic-encapsulated body and the second plastic-encapsulated body are formed of different materials.

12. The semiconductor package of claim 1, wherein the third chip is in plural and electrically connected to each other through the third bonding wire.

13. A method of manufacturing a semiconductor package, the method comprising:
providing a substrate;
stacking a plurality of first chips on the substrate, and electrically connecting each of the plurality of first chips to the substrate through a first bonding wire;
disposing a second chip on the substrate, the second chip being spaced apart from the plurality of first chips in a first direction parallel to an upper surface of the substrate, wherein the second chip comprises a dummy pad disposed on an upper surface of the second chip;
disposing a wire finger on the dummy pad and electrically connecting the wire finger to the substrate through a second bonding wire;
performing a first plastic-encapsulating process to form a first plastic-encapsulated body, the first plastic-encapsulated body covering the plurality of first chips and the second chip on the substrate and exposing an upper surface of the wire finger;
disposing a third chip on an upper surface of the first plastic-encapsulated body and electrically connecting the third chip to the wire finger through a third bonding wire; and
performing a second plastic-encapsulating process to form a second plastic-encapsulated body, the second plastic-encapsulated body covering the third chip on the first plastic-encapsulated body.

14. The method of claim 13, wherein a first distance between the upper surface of the wire finger and the upper surface of the substrate in a second direction perpendicular to the upper surface of the substrate is equal to or greater than a thickness of the first plastic-encapsulated body between the upper surface of the first plastic-encapsulated body and the upper surface of the substrate in the second direction.

15. The method of claim 14,
wherein the disposing of the wire finger comprises stacking at least one conductive connecting part in the second direction, and
wherein the performing of the first plastic-encapsulating process comprises exposing an upper surface of an uppermost conductive connecting part of the at least one conductive connecting part from the first plastic-encapsulated body.

16. The method of claim 15, wherein each of the at least one conductive connecting part is a metal ball.

17. The method of claim 15, wherein the second bonding wire is connected to a lowermost conductive connecting part of the at least one conductive connecting part, and
wherein the lowermost conductive connecting part is disposed on the dummy pad.

18. The method of claim 13,
wherein the second chip is a circuit chip having an electrical function, and
wherein the disposing of the second chip further comprises electrically connecting the second chip to the substrate through a fourth bonding wire.

19. The method of claim 18,
wherein the second chip further comprises:
a functional pad disposed on the upper surface of the second chip and spaced apart from the dummy pad in the first direction, and
wherein the fourth bonding wire is connected to the functional pad and the substrate.

20. The method of claim 13, wherein the second chip is a dummy chip not having an electrical function.
